(19) United States
(12) Patent Application Publication
(10) Pub. No.: US 2004/0188079 A1
(43) Pub. Date: Sep. 30, 2004

(54) Heat-dissipation module for chip

(75) Inventors: Ing-Jer Chiou, Taipei (TW); Hsi-Chi Chien, Taipei (TW)

Correspondence Address: HAVERSTOCK & OWENS LLP, 162 NORTH WOLFE ROAD, SUNNYVALE, CA, 94086, US

(73) Assignee: Arima Computer Corporation

(21) Appl. No.: 10/404,397

(22) Filed: Mar. 31, 2003

(51) Int. Cl. F28F 1/00; F24H 3/02; F28F 7/00; H05K 7/20

(52) U.S. Cl. 165/185; 165/121; 361/704; 361/697

(57) ABSTRACT

A heat-dissipation module for a chip is disclosed. The heat-dissipation module includes a base having plural fastening holes, an edge, and a contacting surface attached to the chip, a conductive piece connected to the surface of the base and extended from the surface for heat-conducting, a fan set disposed by the edge of the base and connected to the conductive piece for cooling the conductive piece, and plural buffers disposed with respect to the plural fastening holes of the base for providing a cushioning force to facilitate the heat-dissipation module to be assembled.

### FIELD OF THE INVENTION

The present invention is related to a heat-dissipation module, more particularly to a heat-dissipation module for a chip included in a notebook computer.

### BACKGROUND OF THE INVENTION

Recently, small portable computers, such as the increasingly popular notebook computer, continue to become more sophisticated, powerful and more like their larger desktop counterparts in terms of overall versatility of use. A microprocessor of high performance has been incorporated into a portable type electronic equipment for the purpose of increasing the processing speed and the processing capacity. A quantity of heat generated by this microprocessor is larger than the quantity of heat generated by other electronic parts. Therefore, the microprocessor by which a large quantity of heat is generated is locally air-cooled by a heat sink.

Concerning the heat sink used for locally cooling the microprocessor, there is provided a heat sink which is naturally cooled and further forcibly cooled for enhancing the cooling capacity in such a manner that a cooling fan is set on the naturally cooled heat sink. Also, in order to reduce the dimensions of the apparatus, there is provided a heat sink in which a cooling fan is embedded. However, the prior art is disadvantageous in that the height of the heat sink is increased because the heat sink into which the fan is incorporated is attached onto a heating component.

In order to solve the above problems, there is disclosed a technique in which a heating component is cooled by a heat sink in such a manner that the heating component is mounted at a position distant from the heat sink, and the heating component is connected with the heat sink by a heat pipe, and heat which has been generated by the heating component is transmitted to the heat sink via the heat pipe. In the above case, for example, it is possible to arrange the heating component and the heat sink in the transverse direction. Accordingly, the height of the apparatus can be reduced.

In assembly, the heat sink is mounted on the top of the central processing unit (CPU) of the notebook computer and has to be fastened via plural screws passing through the base body of the heat sink. However, the heat sink includes an inequality structure. When a user wants to screw sequentially plural screws, the heat sink stands over the CPU unevenly. The user can't set the heat sink on the top of the CPU smoothly, and even damage the CPU.

Accordingly, there should be a heat-dissipation module for solving the above problems, smoothly dissipating the heat produced by the CPU of the notebook, and being assembled easily.

Therefore, it is tried to rectify those drawbacks and provide a heat-dissipation module for dissipating the heat of the CPU of the notebook and providing a cushioning force to facilitate the heat-dissipation module to be assembled by the present applicant. This invention is a specific heat-dissipation module for solving the above problems, decreasing the noise, and increasing the stability thereof.

### SUMMARY OF THE INVENTION

It is an object of the present invention to provide a heat-dissipation module for solving the prior problems, decreasing the noise, and increasing the stability thereof.

According to the present invention, the heat-dissipation module includes a base having plural fastening hole, an edge, and a contacting surface attached to the chip, a conductive piece connected to the surface of the base and extended from the surface for heat-conducting, a fan set disposed by the edge of the base and connected to the conductive piece for cooling the conductive piece, and plural buffers disposed with respect to the plural fastening holes of the base for providing a cushioning force to facilitate the heat-dissipation module to be assembled.

Certainly, the chip can be a CPU for a notebook computer.

Preferably, the heat-dissipation module further includes plural screws for passing through the fastening holes and fastening the base to cover the chip, thereby the contacting surface attaching thereto the chip.

Certainly, the plural buffers can be elastic pads.

Accordingly, the elastic pads are made of a rubber.

Preferably, each of the plural buffers further includes a through hole.

Preferably, the heat-dissipation module further includes plural screws for sequentially passing through the fastening holes and the through holes and fastening the base to cover the chip, thereby the contacting surface attaching thereto the chip.

It is another object of the present invention to provide a heat-dissipation module, which is easy to assembled, includes a base having plural fastening holes and a contacting surface attached to the chip, and plural buffers disposed with respect to the plural fastening holes of the base for facilitating the heat-dissipation module to be assembled.

Certainly, the chip can be a CPU for a notebook computer.

Preferably, the heat-dissipation module further includes a conductive piece connected to the surface of the base and extended from the surface for heat-conducting, and a fan set disposed by the base and connected to the conductive piece for cooling the conductive piece.

Preferably, the heat-dissipation module further includes plural screws for passing through the fastening holes and fastening the base to cover the chip, thereby the contacting surface attaching thereto the chip.

Certainly, the plural buffers can be elastic pads.

Accordingly, the elastic pads are made of a rubber.

Preferably, each of the plural buffers further includes a through hole.

Accordingly, the heat-dissipation module further includes plural screws for sequentially passing through the fastening holes and the through holes and fastening the base to cover the chip, thereby the contacting surface attaching thereto the chip.

In accordance with another aspect of the present invention, the heat sink for a chip includes a base having plural fastening holes and a contacting surface attached to the chip, and plural buffers disposed below the base for facilitating the heat sink to be assembled.

Certainly, the chip can be a CPU for a notebook computer.

Preferably, the heat sink further includes a conductive piece connected to the surface of the base and extended from the surface for heat-conducting, and a fan set disposed by the base and connected to the conductive piece for cooling the conductive piece.

Accordingly, the heat sink further comprising plural screws for passing through the fastening holes and fastening the base to cover the chip, thereby the contacting surface attaching thereto the chip.

Certainly, the plural buffers can be elastic pads.

Preferably, the elastic pads are made of a rubber.

Certainly, the buffers can be elastic pieces.

In accordance with one aspect of the present invention, the heat-dissipation module for a notebook, includes a base having plural fastening holes, an edge, and a contacting surface attached to the chip, a fan set disposed by the edge of the base and connected to the base for cooling the base, and plural buffers disposed with respect to the plural fastening holes of the base for providing a cushioning force to facilitate the heat-dissipation module to be assembled.

Now the foregoing and other features and advantages of the present invention will be more clearly understood through the following descriptions with reference to the drawings, wherein:

### BRIEF DESCRIPTION OF THE DRAWINGS

FIG. 1 illustrates a heat-dissipation module for a chip according to a preferred embodiment of the present invention; and

FIG. 2 illustrates a heat-dissipation module for a chip according to another preferred embodiment of the present invention.

### DETAILED DESCRIPTION OF THE PREFERRED EMBODIMENT

The primary objective of the present invention is to provide a heat-dissipation module for rectifying the drawbacks of the prior art, decreasing the noise, and increasing the stability thereof.

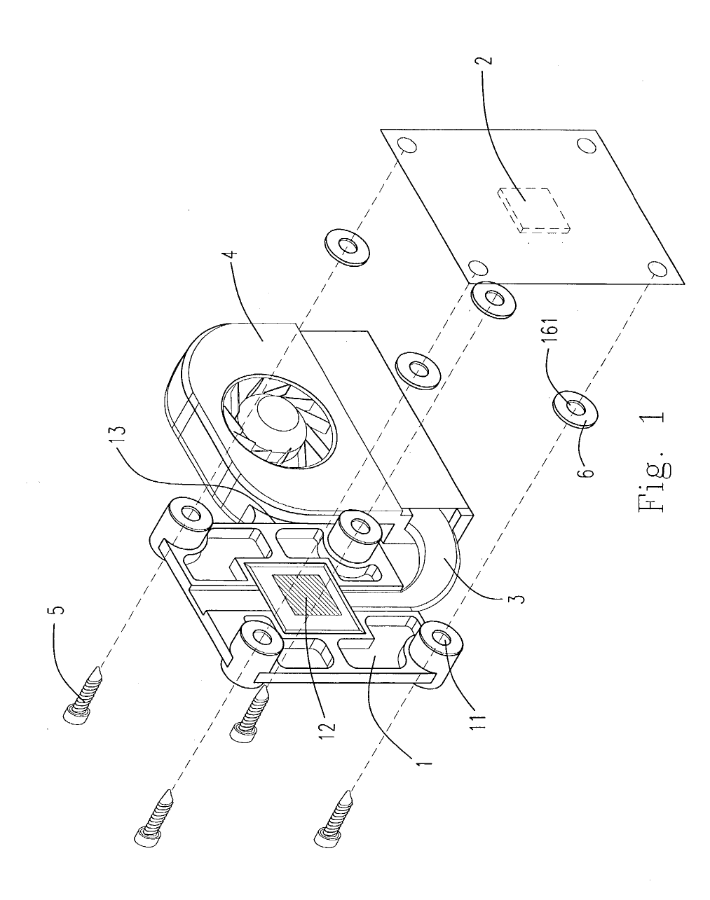

Please refer to FIG. 1. It illustrates a heat-dissipation module for a chip 2 of a notebook computer according to a preferred embodiment of the present invention. In FIG. 1, the heat-dissipation module includes a base 1 having plural fastening hole 11, an edge 13, and a contacting surface 12 attached to the chip 2, a conductive piece 3 connected to the surface 12 of the base 1 and extended from the surface 12 for heat-conducting, a fan set 4 disposed by the edge 13 of the base 1 and connected to the conductive piece 3 for cooling the conductive piece 3, and plural buffers 16 disposed with respect to the plural fastening holes 11 of the base 1 for providing a cushioning force to facilitate the heat-dissipation module to be assembled. Meanwhile the chip 2 can be a CPU for a notebook computer. The heat-dissipation module further includes plural screws 5 for passing through the fastening holes 11 and fastening the base 1 to cover the chip 2, thereby the contacting surface 12 attaching thereto the chip 2. Additionally, the plural buffers 16 are elastic pads and can be made of a rubber.

In application of the preferred embodiment of the present invention, each of the plural buffers 16 further includes a through hole 161, and the heat-dissipation module further includes plural screws 5 for sequentially passing through the fastening holes 11 and the through holes 161 and fastening the base 1 to cover the chip 2, thereby the contacting surface 12 attaching thereto the chip 2.

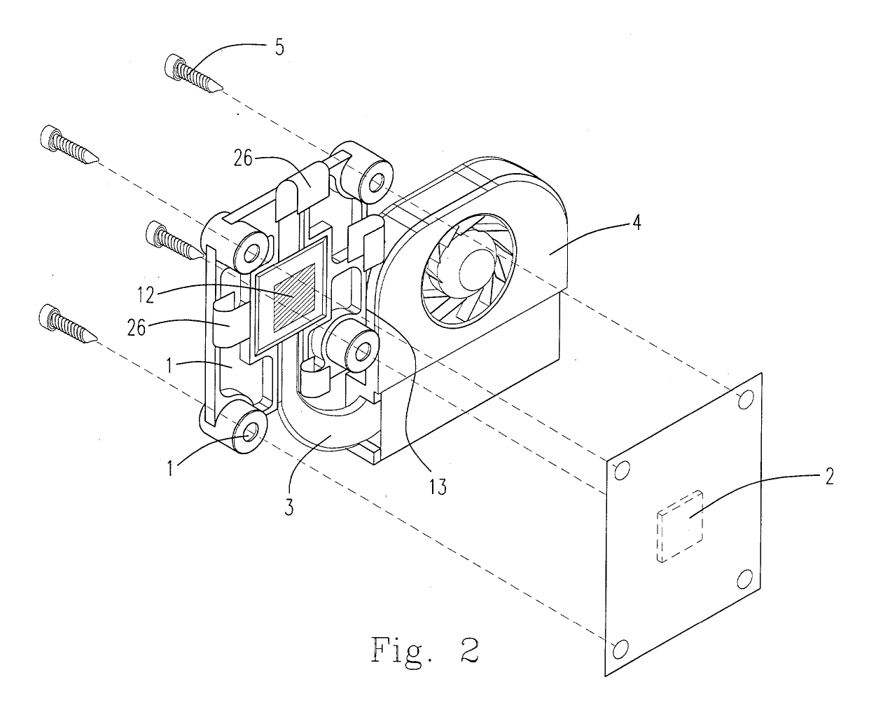

Please refer to FIG. 2. It illustrates a heat-dissipation module for a chip according to another preferred embodiment of the present invention. The heat-dissipation module for a chip 2 of a notebook is easy to assembled. In FIG. 2, the heat-dissipation module includes a base 1 having plural fastening holes 12 and a contacting surface 12 attached to the chip 2, and plural buffers 26 disposed with respect to the plural fastening holes 11 of the base 1 for facilitating the heat-dissipation module to be assembled.

According to the above embodiment of the present invention, the chip 2 can be a CPU for a notebook computer. Certainly, the heat-dissipation module can further include a conductive piece 3 connected to the surface 12 of the base 1 and extended from the surface 12 for heat-conducting, and a fan set 4 disposed by the base 2 and connected to the conductive piece 3 for cooling the conductive piece 3. Meanwhile the heat-dissipation module further includes plural screws 5 for passing through the fastening holes 11 and fastening the base 1 to cover the chip 2, thereby the contacting surface 12 attaching thereto the chip 2. Moreover, the plural buffers 26 can be elastic pads made of a rubber or be elastic pieces.

In conclusion, the present invention possesses many outstanding characteristics, effectively improves upon the drawbacks associated with the prior art in practice and application, produces practical and reliable products, bears novelty, and adds to economical utility value.

Although the present invention has been described and illustrated in detail, it is to be clearly understood that the same is by the way of illustration and example only and is not to be taken by way of limitation, the spirit and scope of the present invention being limited only by the terms of the appended claims.

What is claimed is:

1. A heat-dissipation module for a chip, comprising
a base having plural fastening holes, an edge, and a contacting surface attached to said chip;
a conductive piece connected to said surface of said base and extended from said surface for heat-conducting;
a fan set disposed by said edge of said base and connected to said conductive piece for cooling said conductive piece; and
plural buffers disposed with respect to said plural fastening holes of said base for providing a cushioning force to facilitate said heat-dissipation module to be assembled.

2. The heat-dissipation module according to claim 1, wherein said chip is a CPU for a notebook computer.

3. The heat-dissipation module according to claim 1 further comprising plural screws for passing through said fastening holes and fastening said base to cover said chip, thereby said contacting surface attaching thereto said chip.

4. The heat-dissipation module according to claim 1, wherein said plural buffers are elastic pads.

5. The heat-dissipation module according to claim 4, wherein said elastic pads are made of a rubber.

6. The heat-dissipation module according to claim 1, wherein each of said plural buffers further comprises a through hole.

7. The heat-dissipation module according to claim 6 further comprising plural screws for sequentially passing through said fastening holes and said through holes and fastening said base to cover said chip, thereby said contacting surface attaching thereto said chip.

8. A heat-dissipation module for a chip, comprising
a base having plural fastening holes and a contacting surface attached to said chip; and
plural buffers disposed with respect to said plural fastening holes of said base for facilitating said heat-dissipation module to be assembled.

9. The heat-dissipation module according to claim 8, wherein said chip is a CPU for a notebook computer.

10. The heat-dissipation module according to claim 8 further comprising:
a conductive piece connected to said surface of said base and extended from said surface for heat-conducting; and
a fan set disposed by said base and connected to said conductive piece for cooling said conductive piece.

11. The heat-dissipation module according to claim 8 further comprising plural screws for passing through said fastening holes and fastening said base to cover said chip, thereby said contacting surface attaching thereto said chip.

12. The heat-dissipation module according to claim 8, wherein said plural buffers are elastic pads.

13. The heat-dissipation module according to claim 12, wherein said elastic pads are made of a rubber.

14. The heat-dissipation module according to claim 8, wherein each of said plural buffers further comprises a through hole.

15. The heat-dissipation module according to claim 14 further comprising plural screws for sequentially passing through said fastening holes and said through holes and fastening said base to cover said chip, thereby said contacting surface attaching thereto said chip.

16. A heat sink for a chip comprising:
a base having plural fastening holes and a contacting surface attached to said chip; and
plural buffers disposed below said base for facilitating said heat sink to be assembled.

17. The heat sink according to claim 16, wherein said chip is a CPU for a notebook computer.

18. The heat sink according to claim 16 further comprising:
a conductive piece connected to said surface of said base and extended from said surface for heat-conducting; and
a fan set disposed by said base and connected to said conductive piece for cooling said conductive piece.

19. The heat sink according to claim 16 further comprising plural screws for passing through said fastening holes and fastening said base to cover said chip, thereby said contacting surface attaching thereto said chip.

20. The heat sink according to claim 16, wherein said plural buffers are elastic pads.

21. The heat sink according to claim 20, wherein said elastic pads are made of a rubber.

22. The heat sink according to claim 16, wherein said buffers are elastic pieces.

23. A heat-dissipation module for a chip, comprising:
a base having plural fastening holes, an edge, and a contacting surface attached to said chip;
a fan set disposed by said edge of said base and connected to said base for cooling said base; and
plural buffers disposed with respect to said plural fastening holes of said base for providing a cushioning force to facilitate said heat-dissipation module to be assembled.
